(19) United States
(12) Patent Application Publication
(10) Pub. No.: US 2016/0284887 A1
(43) Pub. Date: Sep. 29, 2016

(54) CRACK PREVENTION FOR SOLAR CELLS

(71) Applicants: Gabriel Harley, Mountain View, CA (US); Michael Morse, San Jose, CA (US)

(72) Inventors: Gabriel Harley, Mountain View, CA (US); Michael Morse, San Jose, CA (US)

(21) Appl. No.: 14/672,075

(22) Filed: Mar. 27, 2015

(51) Int. Cl. H01L 31/0236; H01L 31/05; H01L 31/0224

(52) U.S. Cl. CPC H01L 31/02366; H01L 31/02245; H01L 31/0516

(57) ABSTRACT

Methods of fabricating a solar cell, and resulting solar cells having grooves to inhibit cracking, are described. In an example a solar cell can include a semiconductor substrate having a groove disposed in a front side of the solar cell. In an embodiment, the groove is configured to inhibit cracking at the semiconductor substrate. In embodiment, the solar cell can have a metallization structure coupled to a back side of the semiconductor substrate.

### BACKGROUND

Photovoltaic (PV) cells, commonly known as solar cells, are devices for conversion of solar radiation into electrical energy. Generally, solar radiation impinging on the surface of, and entering into, the substrate of a solar cell creates electron and hole pairs in the bulk of the substrate. The electron and hole pairs migrate to p-doped and n-doped regions in the substrate, thereby creating a voltage differential between the doped regions. The doped regions are connected to the conductive regions on the solar cell to direct an electrical current from the cell to an external circuit.

### BRIEF DESCRIPTION OF THE DRAWINGS

FIG. 1 illustrates an example solar cell, according to some embodiments.

FIG. 2 illustrates a flow chart representation of a method for fabricating a solar cell, according to some embodiments.

FIG. 3 illustrates a cross-sectional view of a solar cell prior to a scribing process, according to some embodiments.

FIG. 4 illustrates a cross-sectional view of a solar cell subsequent to a scribing process, according to some embodiments.

FIGS. 5A-5C illustrate plan views for example scribing processes, according to some embodiments.

FIGS. 6-8 illustrate example solar cells having a groove configured to inhibit cracking, according to some embodiments.

FIG. 9 illustrates an example solar cell having a plurality of grooves configured to inhibit cracking, according to some embodiments.

### DETAILED DESCRIPTION

The following detailed description is merely illustrative in nature and is not intended to limit the embodiments of the subject matter of the application or uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” groove does not necessarily imply that this groove is the first groove in a sequence; instead the term “first” is used to differentiate this groove from another groove (e.g., a “second” groove).

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In the following description, numerous specific details are set forth, such as specific operations, in order to provide a thorough understanding of embodiments of the present disclosure. It will be apparent to one skilled in the art that embodiments of the present disclosure may be practiced without these specific details. In other instances, well-known techniques are not described in detail in order to not unnecessarily obscure embodiments of the present disclosure.

The specification first describes an example method for forming solar cells having grooves configured to inhibit cracking and relieve stress on a solar cell. The specification then describes example solar cells that can include the disclosed grooves to inhibit cracking and relieve stress, followed by a more detailed explanation of various embodiments of the solar cells having groove structures. Various examples are provided throughout.

Cracking in solar cells can lead to power loss and reliability problems. In an example, for silicon based solar cells, defects, e.g., such as cracks, may be generated within a silicon substrate during and/or after the solar cell manufacturing process. Cracking can be caused by mechanical and/or thermal stress. Single-crystalline silicon solar cells can be especially sensitive to crack growth and/or propagation because, once cracked, no barriers or crack prevention mechanisms exist within the solar cell, such that a crack can continue from one side of a solar cell to another side. In one example, force from a soldering pin on a contact pad of a solar cell during a soldering process can create cracks. Cracking in the solar cell can cause the power loss and/or solar cell breakage.

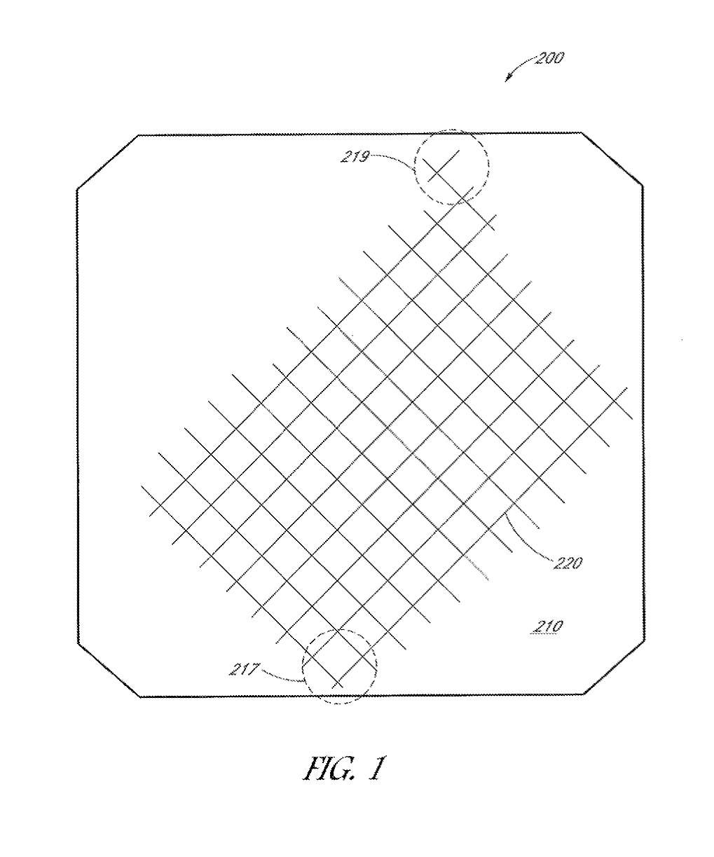

FIG. 1 illustrates an example solar cell having cracks. In this example, the cracks 220 are formed on a silicon substrate 210 of the solar cell 200. As shown, the cracks 220 propagate from one side 217 of the solar cell to another side 219. A method of fabricating a solar cell and solar cells having grooves to inhibit crack formation are presented.

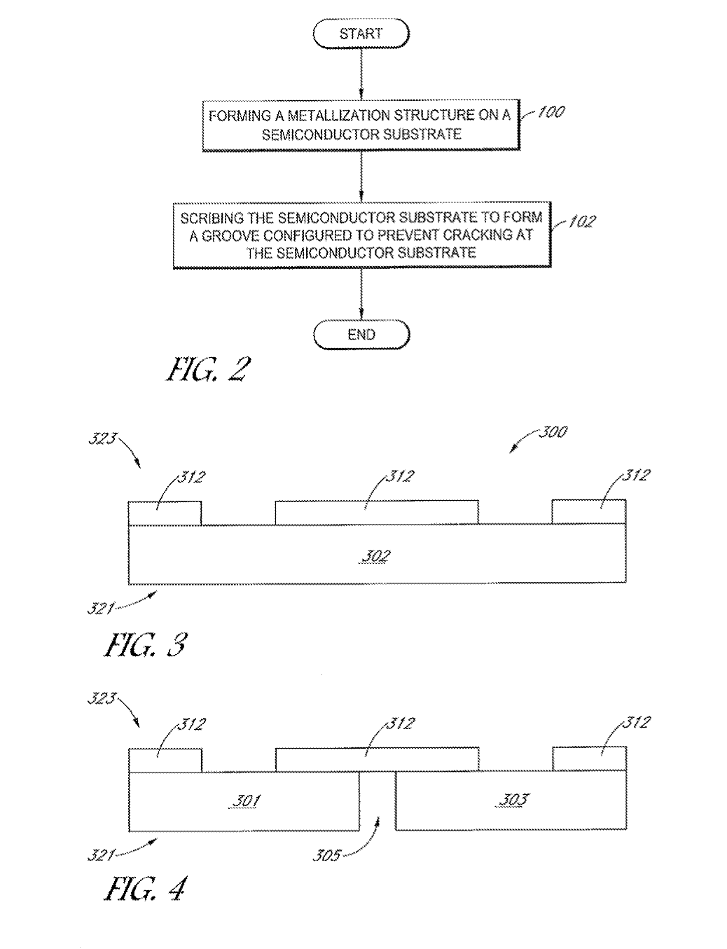

Turning now to FIG. 2, a flow chart illustrating a method for fabricating a solar cell is shown, according to some embodiments. In various embodiments, the method of FIG. 2 can include additional (or fewer) blocks than illustrated. In an example, subsequent to scribing at 102, an encapsulating material can be formed in the groove to provide structural support to semiconductor substrate.

At 100, a metallization structure coupled to a back side of a solar cell can be formed. In an embodiment, the metallization structure can be an interdigitated metal contact region. In one embodiment, forming the metallization structure can include patterning a metal foil formed on the back side of a solar cell. In an embodiment, forming the metallization structure can include plating one or more metal films on the back side the solar cell.

At 102, a scribing process can be performed on the semiconductor substrate to form a groove on a front side of the solar cell, which is the side that faces the sun during normal operation. In an embodiment, the groove can be configured to inhibit cracking and/or relieve stress at the semiconductor substrate. In an embodiment, the groove can be configured to inhibit cracking from forming at the semiconductor substrate. In an example, the groove can inhibit cracks from forming at locations where cracks do not originally exist. In an embodiment, the groove can be configured to inhibit cracking from growing and/or propagating. In an example, the groove can inhibit an existing crack from further propagating throughout the semiconductor substrate. In an embodiment, inhibiting cracking can include inhibiting cracking from forming, growing and/or propagating.

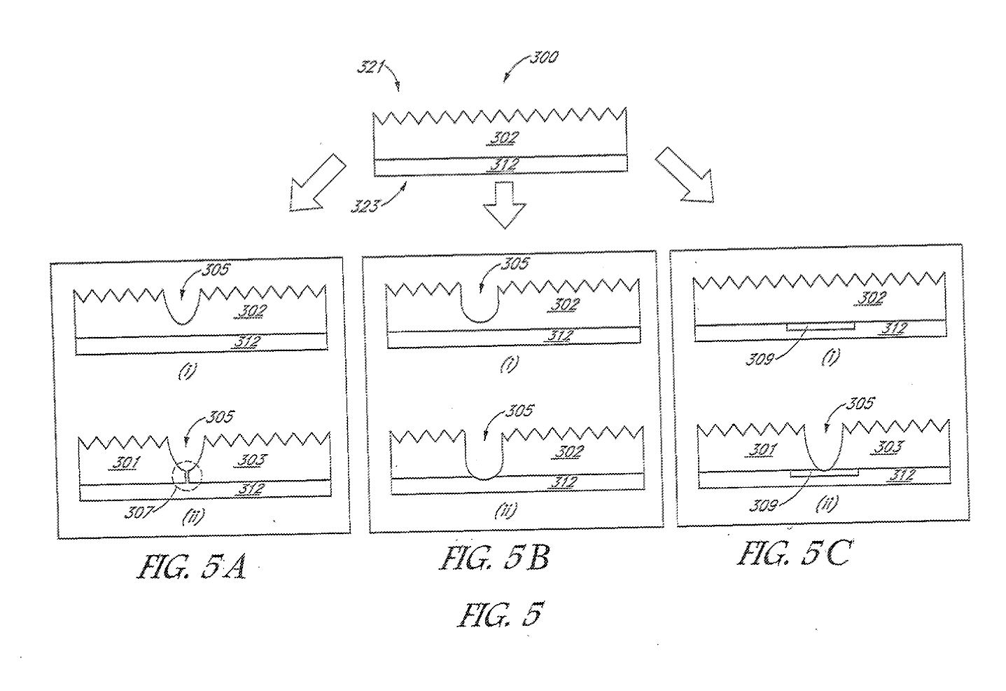

In one example, stress at the substrate may be caused by bending at a moment (e.g., a groove) and the stress can be proportional to the length of the substrate squared. In an embodiment, the groove can be configured to segment a semiconductor substrate into separate pieces (e.g., a first and a second portion of the semiconductor substrate as shown in FIG. 4) which can thus inhibit cracking (e.g., caused by stress) at the individual pieces of the semiconductor substrate.

In an embodiment, the scribing can be performed to form a groove that at least partially surrounds a portion of the solar cell which is prone to mechanical pressure and/or stress or thermal loads. In an example, the scribing can be performed to form a groove that at least partially surrounds a contact pad region or an edge of the solar cell. Contact pad region is used herein to refer to a region of the silicon substrate (e.g., on the front side of the solar cell) that corresponds to a contact pad (e.g., on a back side of the solar cell). In some embodiments, a force can be applied at the contact pad (e.g., during stringing of solar cells), which can create cracks at or near the contact pad region.

In various embodiments, scribing can be performed with a laser, a mechanical scribing device (e.g., saw), or some combination thereof. In one embodiment, the scribing can form a groove having a depth in the range of 25%-75% of the thickness of the semiconductor substrate, whereas in another embodiment, the groove can formed through a full depth of the semiconductor substrate. In an embodiment, the groove formed can be in a line (e.g., continuous or dashed), a curved line, or some other shape, the shape of which can be based on the type of stress that the groove is intended to inhibit. In an embodiment, multiple grooves configured to inhibit cracking and/or relieve stress can be formed in the substrate.

In an embodiment, in addition to scribing grooves to inhibit crack formation and/or to relieve stress, scribing can also include forming a multi-diode solar cell. For example, scribing can form a plurality of sub-cells, each of the sub-cells comprising a singulated and physically separated portion of the semiconductor substrate having a groove between adjacent ones of the singulated and physically separated semiconductor substrate portions. Thus, one set of grooves can be grooves that separate sub-cells from one another and one or more other grooves can be grooves that are configured to inhibit cracking at the semiconductor substrate.

In an embodiment, an encapsulating material can be formed in the groove(s) to provide structural support to semiconductor substrate. In one embodiment, the encapsulating material can be ethylene vinyl alcohol (EVA) and/or poly-olefin.

With reference to FIG. 3, a solar cell 300 includes a substrate 302 having a metallization structure 312 disposed thereon. In an embodiment, the solar cell 300 can have a front side 321 and a back side 323, where the front side is opposite the back side 323. The solar cell 300 can include alternating N-type and P-type regions in or above the semiconductor substrate 302. In an embodiment, the semiconductor substrate 302 is a silicon substrate. In one embodiment, the semiconductor substrate 302 is a single-crystalline silicon substrate. In one embodiment, the metallization structure 312 is a metal foil (e.g., aluminum foil and/or aluminum alloy). In an embodiment, the metallization structure 312 is a plated metal (e.g., a copper or a copper alloy).

FIG. 4 illustrates the solar cell 300 after performing a scribing process to form a groove. In one embodiment, the solar cell 300 includes a first and a second portion 301, 303 having a groove 305 adjacent to both the first and second portions 301, 303 of the semiconductor substrate, as shown. In an embodiment, the groove 305 is formed on the front side 321 of the solar cell 300. In one embodiment, the groove 305 can physically separate the first and second portion of the semiconductor substrate. In other embodiments, the groove may not entirely separate the two portions of the semiconductor substrate.

In an embodiment, the first and second portions 301, 303 of the semiconductor substrate are sub-cells, e.g., complete solar cells and/or diode structures. In an embodiment, a portion of the metallization structure 312 bridges the first and second portions and/or sub-cells 301, 303 of the semiconductor substrate. In the same embodiment, metal structure 312 can connect the sub-cells 301, 303 in series or parallel configurations.

In an embodiment, an encapsulating material can be disposed in the groove 305 to provide structural support to semiconductor substrate. In one embodiment, the encapsulating material can be ethylene vinyl alcohol (EVA) and/or poly-olefin.

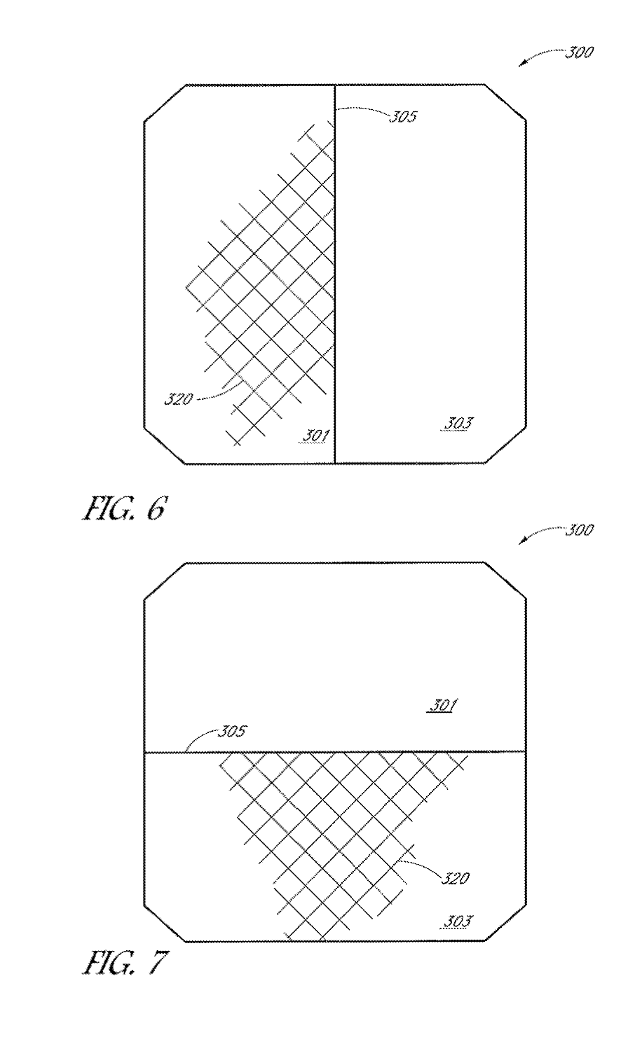

FIGS. 5A-5C illustrate pathways for scribing the semiconductor substrate to form a groove including example grooves, according to some embodiments. Referring to FIGS. 5A-5C, a solar cell 300 having a front and back side 321, 323 is shown, where the solar cell 300 includes a silicon substrate 302 and a metallization structure 312 on a back side 323 of the semiconductor substrate 302.

Referring to FIG. 5A, a scribe plus break approach is depicted where (i) the semiconductor substrate 302 is partially scribed (e.g., the groove can have approximately 25%-75% depth) and then (ii) cracked along the break 307 to terminate at the metallization structure 312. Referring to FIG. 5B, a scribe-only approach is depicted where (i) the semiconductor substrate 302 is partially scribed (e.g., approximately the groove can have 25%-75% depth) and (ii) the groove is formed through a full depth of the semiconductor substrate and/or partially into the metallization structure 312. Referring to FIG. 5C, a scribe plus damage buffer break approach is depicted where the scribe of the semiconductor substrate 302 is performed through the full depth of the semiconductor substrate and then stops on (or partially into) a damage buffer region 309 distinct from the metallization structure 312. In any of these cases, a laser can be used to scribe the solar cell 300, as shown. In an embodiment, a pico-second, nano-second or longer wavelength can be used. Note that in some embodiments, the solar cell can include a groove that is not the full depth of the substrate. For example, a groove may be formed at FIG. 5A (i) without doing the cracking at FIG. 5A (ii).

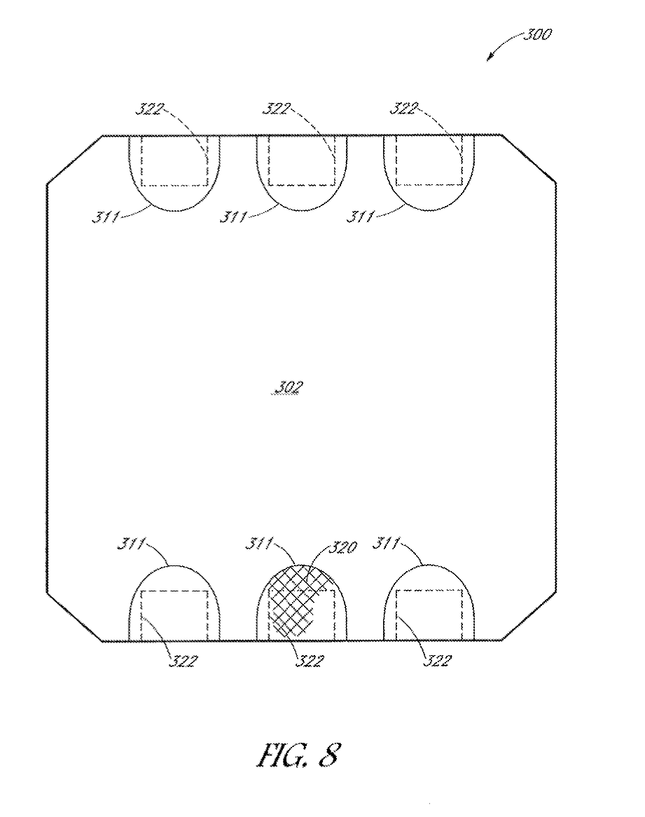

FIGS. 6-11 illustrate different example configurations for grooves configured to inhibit cracking on a front surface of a solar cell, where various embodiments are presented throughout. As shown, the solar cell 300 of FIGS. 6-11 have similar reference numbers to the solar cell 300 of FIGS. 3-5, wherein like reference numbers refer to similar elements throughout the figures.

With reference to FIG. 6, an example solar cell having a groove configured to inhibit cracking is shown, according to some embodiments. In an embodiment, the groove 305 is disposed vertically across a front side the solar cell 300. A crack 320 is shown to propagate within a first portion 301 of a semiconductor substrate of the solar cell 300 but stops at the groove 305, where a second portion 303 of the semiconductor substrate has no cracking. In an embodiment, the groove 305 of FIG. 6 inhibits the cracking 320 at the first portion 301 from propagating to the second portion 303 the semiconductor substrate. In one embodiment, the first and second semiconductor portions 301, 303 are sub-cells of a parent cell whereas in another embodiment, the first and second semiconductor portions 301, 303 may not be completely separated in the substrate.

FIG. 7 illustrates another example solar cell having a groove configured to inhibit cracking, according to some embodiments. In an embodiment, the groove 305 is disposed horizontally across a front side the solar cell 300. A crack 320 is shown to propagate within the second portion 303 but stops at the groove 305, where the first portion 301 has no cracking. In an embodiment, the groove 305 of FIG. 7 inhibits the cracking 320 at a second portion 303 from propagating to a first portion 301 of the semiconductor substrate. In one embodiment, the first and second semiconductor portions 301, 303 are sub-cells of a parent cell whereas in another embodiment, the first and second semiconductor portions 301, 303 may not be completely separated in the substrate.

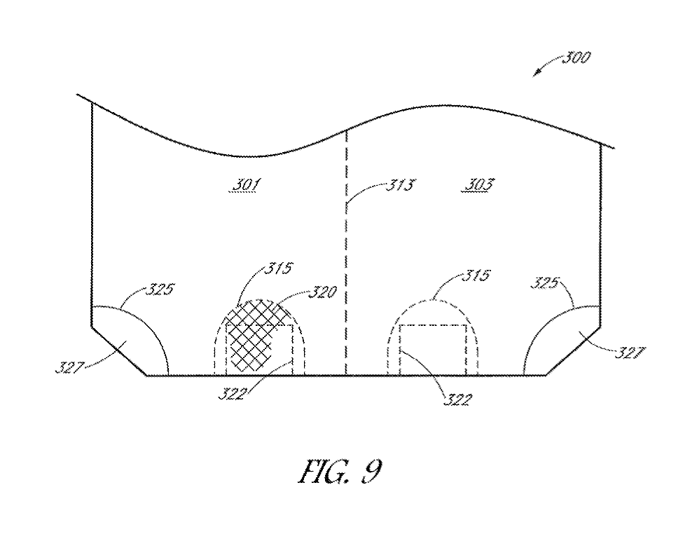

With reference to FIG. 8, still another example solar cell having a groove configured to inhibit cracking is shown, according to some embodiments. In an embodiment, a plurality of grooves 311 on a front side of a semiconductor substrate 302 at least partially surround a plurality of contact pad regions 322 of the solar cell. In an embodiment, a contact pad region 322 is a region on front side of the solar cell 300 that is opposite a contact pad on a back side of the solar cell 300. In an embodiment, as shown, the groove 311 of FIG. 8 can inhibit the cracking 320 at the contact pad region 322 from propagating throughout to semiconductor substrate 302.

FIG. 9 illustrates a portion of an example solar cell having grooves configured to inhibit cracking, according to some embodiments. In an embodiment, the plurality of grooves 313, 315, 325 are disposed on a front side the solar cell 300. In an embodiment, a first groove 313 is disposed vertically on the portion of the solar cell 300. In an embodiment, the groove 313 is formed in a dashed line. In an embodiment, the solar cell 300 can have a first and second portion 301, 303 of a semiconductor substrate as shown. In an embodiment, the first and second portions 301, 303 are sub-cells of a parent cell whereas in another embodiment, the first and second semiconductor portions 301, 303 may not be completely separated in the substrate.

In an embodiment, a plurality of second grooves 315 at least partially surround contact pad regions 322. In an embodiment, a contact pad region 322 is a region on front side of the solar cell 300 that is opposite a contact pad on a back side of the solar cell 300. A crack 320 is shown to propagate only within the region enclosed by the groove 315. In an embodiment, the groove 315 of FIG. 9 inhibits the cracking 320 from propagating throughout the first portion 301 of a semiconductor substrate. In an embodiment, the grooves 315 are formed in dashed lines.

In an embodiment, a plurality of third grooves 325 at least partially surround edges 327 of the solar cell 300. In an embodiment, the grooves 325 are formed in lines (e.g., curved, straight).

In an embodiment, the sub-cells can have a plurality of grooves for inhibiting cracking, e.g., the first, second and third grooves 313, 315, 325, as shown. In an embodiment, an encapsulant material can be disposed in any of the grooves 313, 315, 325. In one embodiment, the encapsulating material can be ethylene vinyl alcohol (EVA) and/or poly-olefin.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A solar cell, comprising:
a semiconductor substrate having a groove disposed in a front side of the solar cell, wherein the groove is configured to inhibit cracking at the semiconductor substrate; and
a metallization structure coupled to a back side of the semiconductor substrate.

2. The solar cell of claim 1, wherein the groove is configured to relieve stress at the semiconductor substrate.

3. The solar cell of claim 1, wherein the groove has a depth in the range of 25%-75% of the thickness of the semiconductor substrate.

4. The solar cell of claim 1, wherein the groove is formed through a full depth of the semiconductor substrate.

5. The solar cell of claim 1, wherein the groove physically separates a first and second portion of the semiconductor substrate; and
the metallization structure is coupled to the first and second portions of the semiconductor substrate.

6. The solar cell of claim 1, wherein the groove is a line or a dashed line.

7. The solar cell of claim 1, wherein the groove at least partially surrounds a contact pad or an edge of the solar cell.

8. The solar cell of claim 1, further comprising the semiconductor substrate having another groove disposed in a front side of the solar cell, wherein the groove and the other groove are configured to inhibit cracking at the semiconductor substrate.

9. The solar cell of claim 1, further comprising an encapsulating material disposed in the groove.

10. A solar cell, comprising:
a plurality of sub-cells, each of the sub-cells comprising a singulated and physically separated semiconductor substrate portion, wherein adjacent ones of the singulated and physically separated semiconductor substrate portions have a first groove there between;
a second groove disposed in a front side of a sub-cell of the plurality of sub-cells, wherein the second groove is configured to inhibit cracking at the semiconductor substrate of the sub-cell; and
a metallization structure coupling the plurality of sub-cells together.

11. The solar cell of claim 10, wherein the second groove is configured to relieve stress at the semiconductor substrate.

12. The solar cell of claim 10, wherein the second groove is a line or a dashed line.

13. The solar cell of claim 10, wherein the second groove at least partially surrounds a contact pad or an edge of the sub-cell.

14. The solar cell of claim 10, wherein the solar cell further comprises an encapsulating material disposed in the second groove.

15. A method of fabricating a solar cell, the method comprising:
forming a metallization structure coupled to a back side of a semiconductor substrate; and
scribing the semiconductor substrate to form a groove on a front side of the solar cell configured to inhibit cracking at the semiconductor substrate.

16. The method of claim 15, wherein the scribing forms a groove configured to relieve stress at the semiconductor substrate.

17. The method of claim 15, wherein the scribing comprises scribing with a laser.

18. The method of claim 15, further comprising forming an encapsulating material in the groove.

19. The method of claim 15, wherein scribing the semiconductor substrate comprises scribing to form a groove partially surrounding a contact pad or an edge of the solar cell.

20. The method of claim 15, wherein the scribing comprises forming a plurality of sub-cells, each of the sub-cells comprising a singulated and physically separated portion of the semiconductor substrate having a respective groove between adjacent ones of the singulated and physically separated semiconductor substrate portions and another groove disposed in the front side of a sub-cell of the plurality of sub-cells, wherein the second groove is configured to inhibit cracking at the semiconductor substrate of the sub-cell and the metallization structure couples the plurality of sub-cells to one another.
